(19) United States
(12) Patent Application Publication
(10) Pub. No.: US 2009/0149014 A1
(43) Pub. Date: Jun. 11, 2009

(54) METHOD FOR PRODUCING A SEMICONDUCTOR DEVICE

(76) Inventors: Norimitsu NIE, Kashiba-shi (JP); Masahiro HORIO, Fukuyama-shi (JP); Keiichi SAWAI, Fukuyama-shi (JP); Yuji WATANABE, Fukuyama-shi (JP); Yasuhiro KOYAMA, Fukuyama-shi (JP); Katsuji KAWAKAMI, Fukuyama-shi (JP)

Correspondence Address: NIXON & VANDERHYE, PC, 901 NORTH GLEBE ROAD, 11TH FLOOR, ARLINGTON, VA, 22203, US

(21) Appl. No.: 12/098,610

(22) Filed: Apr. 7, 2008

(30) Foreign Application Priority Data
Apr. 10, 2007 (JP) P2007-102449

(51) Int. Cl. H01L 21/60

(52) U.S. Cl. 438/613; 257/E21.508; 438/677; 438/754

(57) ABSTRACT

At step S101, a TiW film is formed by a sputtering method so as to cover a surface protection film and pad electrodes formed on a surface of a semiconductor element. Subsequently, an Au film is formed on the TiW film. At step S103, Au bumps are formed on the Au film using the Au film as a plating electrode. At step S105, unnecessary parts of the Au film are removed. At step S106, unnecessary parts of the TiW film are removed. At step S107, iodine left in areas where the unnecessary parts of the TiW film have been removed, is removed.

This nonprovisional application claims priority under 35 U.S.C. §119(a) on Patent Application No(s). 2007-102449 filed in Japan on Apr. 10, 2007, the entire contents of which are hereby incorporated by reference.

### BACKGROUND OF THE INVENTION

The present invention relates to a method for producing a semiconductor device used for, for example, a semiconductor integrated circuit.

Semiconductor elements tend to reduce in size with becoming finer and increase in the number of pad electrodes by the pursuit of higher functionality. As a result, the pitch of the pad electrodes tends to reduce, and the pitch of the order of 20 μm to 50 μm is a reality.

Furthermore, as a technique of mounting a semiconductor element, there has been established and has been mainstream a technique in which Au bumps are formed on pad electrodes, then the semiconductor element is mounted on a tape via the Au bumps, and then the semiconductor element mounted on the tape is installed in various equipment such as, for example, a large thin-film transistor (TFT) panel module.

Under such a circumstance, a technique of forming Au bumps with a small pitch will become important more and more in the future.

In the technique of forming Au bumps, using an Au film, formed by a sputtering method, as a plating electrode, Au bumps are formed on the Au film by a plating method, and then unnecessary parts of the Au film are removed. As an etchant used for the removal, an iodine solution containing iodine has been proposed.

In JP 2001-148401 A, a potassium iodide solution or an ammonium iodide solution is used as an etchant in the process of removing the plating electrode parts that become unnecessary after the plating process.

JP 5-67620 A discloses finding of a phenomenon in which an etchant left after etching the unnecessary plating electrode parts after plating results in the progress of etching of the remaining plating electrode parts directly below Au bumps due to aged deterioration after mounting the element, and finally peels the Au bumps off.

For this reason, in JP 5-67620 A, a countermeasure changing the process of forming Au bumps has been proposed to prevent the etchant from being left for the purpose of increasing the reliability.

The countermeasure will be concretely described below.

In the countermeasure, a plating electrode is formed first on the whole surface of a wafer including a plurality of semiconductor elements by sputtering, and then photosensitive resist is applied on the whole surface of the plating electrode.

Next, the photosensitive resist is patterned in a predetermined shape. The patterning is performed in such a way that parts of the plating electrode that will become unnecessary are exposed.

Next, the plating electrode is etched using the patterned photosensitive resist as a mask to remove the unnecessary plating electrode parts, and then the photosensitive resist is removed and the wafer is washed with pure water.

Next, the whole surface of the wafer is coated with photosensitive polyimide, which is then patterned so as to expose parts of the remaining plating electrode.

Next, Au bumps are formed, by a wet plating method, on the parts of the plating electrode that are exposed from the photosensitive polyimide.

Next, the wafer is burned at a predetermined temperature to make the photosensitive polyimide into polyimide and reduce the thickness of the photosensitive polyimide in half. As a result, part of the Au bumps protrude from the photosensitive polyimide which has been made into polyimide.

Like this, in the countermeasure, the Au bumps are formed after removing the unnecessary plating electrode parts and washing the wafer with pure water.

However, the countermeasure has a problem that the production cost increases because the countermeasure significantly changes the process of forming Au bumps from a conventional process of forming Au bumps and uses a polyimide film which is not used in the conventional process.

Furthermore, with regard to a method of mounting a semiconductor element on a tape, in recent years, it has progressed to reduce the pad electrode pitch, so that a method of mounting a semiconductor on a tape with leads attached to the tape and filling the gap between the semiconductor and the tape has become mainstream. However, there has been a case that a significant reduction in the reliability is seen in a semiconductor device having such a mounting structure.

### SUMMARY OF THE INVENTION

It is therefore an object of the present invention to provide a method for producing a semiconductor device which is able to increase the reliability of the semiconductor device and prevent the production cost from increasing.

The present inventors have determined that the cause of the reduction in the reliability of a semiconductor device having the mounting structure in which the gap between the semiconductor element and a tape with leads adhering thereto is filled with resin is that a space is formed by peeling or detachment of the resin from the surface of the semiconductor element and a solution including a halogen is produced in the space. This will be described in detail below with reference to FIG. 2 showing such a mounting structure.

As shown in FIG. 2, a semiconductor element 1 has pad electrodes 2 on a surface of it. A TiW film 4, an Au film 5, and an Au bump 7 are formed on each of the pad electrodes 2.

The gap between a tape 9 and a surface protection film 3 is filled with resin 10.

As is apparent from FIG. 2, when the gap between the semiconductor element 1 and the tape 9 is narrowed, the thickness of the resin 10 filling the gap is reduced accordingly. In that case, when the resin 10 has been peeled from the surface of the semiconductor 1 due to foreign substances and the like between the semiconductor element 1 and the tape 9, water easily passes through the tape 9 and the resin 10 and gathers in the space 11 made by the peel-off of the resin 10. As a result, a solution including residual iodine, which had been stuck to the surface protection film 3, is produced.

In this state, an electric field is applied between the Au bumps 7 when the semiconductor element is operated, so that the migration of Au is caused by electrolysis, water, and halogen (iodine). At that time, Au 12 grows between the Au bumps 7, and the Au bumps are electrically shorted to each other, so that the semiconductor 1 cannot perform the original or intended function, and thereby the reliability is significantly reduced. The mechanism of the occurrence of this problem was found out first by the present inventors.

As long as the present inventors know, there was nothing that proposed to remove the residual iodine from the surface of the semiconductor device, mentioning, as a problem, about iodine left on the surface of the semiconductor after having been formed with Au bumps.

The present invention provides a method for producing a semiconductor device which comprises a semiconductor element provided with pad electrodes on a surface thereof, comprising:

forming a metal film on the surface of the semiconductor element and on the pad electrodes;

forming metal bumps on the metal film in such a way that the metal bumps are aligned with the pad electrodes;

removing, by wet etching, the metal film in areas where the metal film is not laid on the pad electrodes; and

removing a halogen in the areas from which the metal film has been removed.

According to the method for producing a semiconductor device configured as above, those parts of the metal film that are not laid on the pad electrodes are removed by wet etching and then the halogen is removed from the areas where the metal film has been removed. As a result of this, the migration of metallic atoms constituting the bump is prevented from occurring when the semiconductor element operates.

Thus, the bumps are prevented from being electrically shorted to each other and thereby the reliability of the semiconductor device is increased.

Furthermore, those parts of the metal film that are not laid on the pad electrodes, that is, the metal film parts which will become unnecessary are removed and then halogen is removed, so that the process of forming the Au bumps needs not be significantly changed from a conventional process of forming Au bumps, and thereby the production cost is prevented from increasing.

In one embodiment, the metal film includes an Au film.

According to the method for producing a semiconductor device of this embodiment, the metal film includes an Au film, so that electrical resistances between the pad electrodes and the bumps are reducible.

In one embodiment, the metal film is used as a plating electrode to form the bumps by an electrolytic plating method.

According to the method for producing a semiconductor device of this embodiment, the metal film is used as a plating electrode to form bumps by an electrolytic plating method, which allows the bumps to be easily and surely formed in desired positions.

In one embodiment, the bumps are formed of Au.

According to the method for producing a semiconductor device of this embodiment, the bumps are formed of Au, which allows the bumps to have lower electrical resistances.

In one embodiment, the halogen is removed with an alkaline chemical solution of a pH of from 9 to 12.

According to the method for producing a semiconductor device of this embodiment, an alkaline chemical solution of a pH between 9 and 12 is used to remove the halogen, so that the halogen is surely removed.

When the pH of the chemical solution is less than 9, the halogen cannot be sufficiently removed, and thereby the effect of preventing the migration of metallic atoms constituting the bumps is reduced.

The chemical solution of a pH exceeding 12 causes an adverse effect such as significantly reducing the adhesion properties of the Au bumps to a semiconductor producing device.

In one embodiment, the halogen is removed with pure water of a temperature of from 50° C. to 75° C.

According to the method for producing a semiconductor device of this embodiment, pure water of a temperature between 50° C. and 75° C. is used to remove the halogen, so that the halogen is surely removed.

Furthermore, the pure water is easily handled as compared with a chemical solution, so that the workability for removal of the halogen is prevented from deteriorating.

When the temperature of the pure water is less than 50° C., the halogen may not be sufficiently removed, and thereby the effect of preventing the migration of metallic atoms constituting the bumps may be reduced.

When the temperature of the pure water exceeds 75° C., this high temperature pure water will adversely affect the semiconductor element.

In one embodiment, the removal of the halogen is performed such that the halogen in the areas where the metal film has been removed is reduced to 300 ng/cm² or less.

According to the method for producing a semiconductor device of this embodiment, because the removal of the halogen is performed such that the halogen in the areas where the metal film has been removed is reduced to 300 ng/cm² or less, the migration of metallic atoms constituting the bumps is surely prevented.

### BRIEF DESCRIPTION OF THE DRAWINGS

The present invention will become more fully understood from the detailed description given hereinbelow and the accompanying drawings which are given by way of illustration only, and thus are not intended to limit the present invention, and wherein:

FIG. 1 is a schematic cross-sectional view showing a state that a semiconductor device produced using a method for producing a semiconductor device according to the present invention has been mounted on a tape;

FIG. 2 is a schematic cross-sectional view for an explanation of a problem which is to be solved by the present invention;

FIG. 3 is a flow chart for performing a method for producing a semiconductor device according to an embodiment of the present invention;

FIG. 4A is a schematic cross-sectional view depicting one step of a method for producing a semiconductor device according to the embodiment;

FIG. 4B is a schematic cross-sectional view depicting one step of the method for producing a semiconductor device according to the embodiment;

FIG. 4C is a schematic cross-sectional view depicting one step of the method for producing a semiconductor device according to the embodiment;

FIG. 4D is a schematic cross-sectional view depicting one step of the method for producing a semiconductor device according to the embodiment;

FIG. 4E is a schematic cross-sectional view depicting one step of the method for producing a semiconductor device according to the embodiment;

FIG. 4F is a schematic cross-sectional view depicting one step of the method for producing a semiconductor device according to the embodiment;

FIG. 4G is a schematic cross-sectional view depicting one step of the method for producing a semiconductor device according to the embodiment;

FIG. 5 is a flow chart for performing a method for producing a semiconductor device according to another embodiment of the present invention.

### DETAILED DESCRIPTION OF THE INVENTION

A method for producing a semiconductor device according to the present invention will be described in detail below with reference to embodiments shown in the figures.

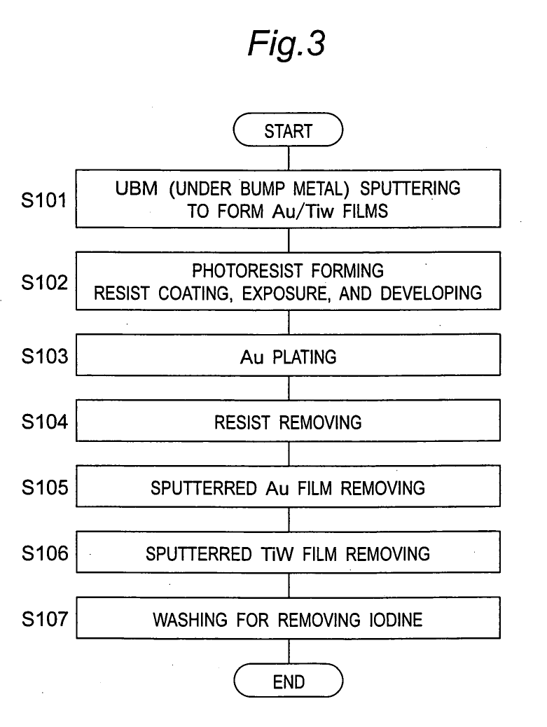

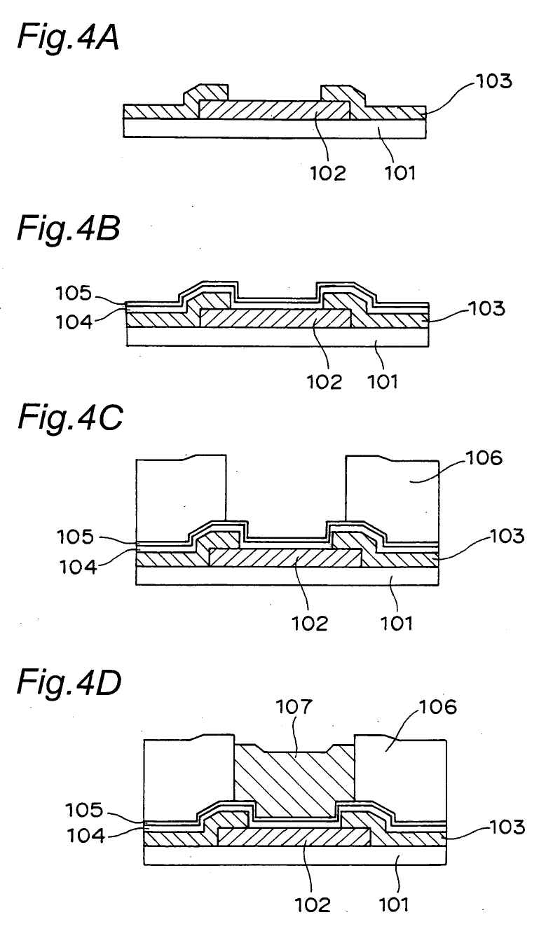

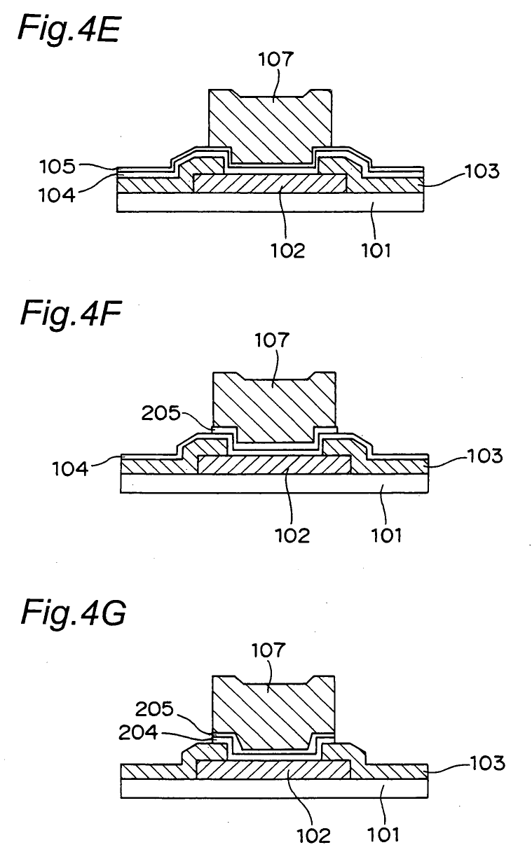

FIG. 3 is a flow chart of a method for producing a semiconductor device according to an embodiment of the present invention. Each of FIGS. 4A to 4G is a schematic cross-sectional view depicting different steps of the method for producing a semiconductor device. Although only one pad electrode 102 is shown in FIGS. 4A to 4G, several hundreds of pad electrodes 102 are actually formed on the surface of a semiconductor element 101.

In the method for producing a semiconductor device, first, pad electrodes 102 and a surface protection film 103 are formed on a semiconductor element 101 as shown in FIG. 4A. Openings are formed in the surface protection film 103, and part of the surfaces of the pad electrodes 102 are exposed from the openings.

Next, at step S101 in FIG. 3, UBM (under bump metal) sputtering is performed. In other words, as shown in FIG. 4B, a TiW film 104 and an Au film 105 are formed in order on the pad electrodes 102 and the surface protection film 103 to cover the pad electrodes 102 and the surface protection film 103 with the TiW film 104 and the Au film 105. The Au film 105 is an example of a metal film.

Next, at step S102 in FIG. 3, photoresist forming is performed. In other words, the surface of the Au film is coated with resist, and then the resist is exposed and developed sequentially to form resist 106 of predetermined shape on the Au film 105. The resist 106 has openings so that part of the Au film 105 is exposed therefrom.

In more detail, resist material is applied to the whole surface of the Au film 105 and exposed using a mask on which a pattern has been inscribed, and then a developer is applied to the resist material. As a result of this, only the resist material on the pad electrodes 102 is removed and corresponding parts of the surface of the Au film 105 are exposed.

Next, at step S103 in FIG. 3, Au plating is performed. In other words, the Au film 105 is dipped in a plating solution and used as a plating electrode to form Au bumps on the Au film 105 exposed from the resist 106 as shown in FIG. 4D. The Au bumps 107 are an example of bumps.

Next, at step S104 in FIG. 3, resist removing is performed. In other words, the resist 106 is removed to obtain a state as shown in FIG. 4E. As a result of this, those parts of the Au film 105 that are not under the Au bumps 107 are exposed.

Next, at step S105 in FIG. 3, removing of the sputtered Au film is performed. Specifically, the exposed Au film 105 is dipped in an iodine solution to be removed. As a result, Au films 205 positioned under the Au bumps 107 as shown in FIG. 4F are obtained.

Next, at step S106 in FIG. 3, removing of the sputtered TiW film is performed. Specifically, those parts of the TiW film 104 that are not under the Au bumps 107 are removed using a hydrogen peroxide solution as an etchant, whereby TiW films 204 positioned under the Au films 205 are obtained as shown in FIG. 4G. As a result of this, those parts of the surface protection-film 103 that are not laid under the Au bumps 107 are exposed. At that time, iodine of 30 ng/cm² to 450 ng/cm² was left on the surface of the surface protection film 103.

Next, at step S107 in FIG. 3, washing for removing the iodine is performed. In other words, washing for removing the iodine which remains on the surface of the surface protection film 103 is performed. At that time, alkaline developer of pH 9 is used for the washing. The alkaline developer is an example of a chemical solution.

More specifically, alkaline developer of pH 9 is dropped to the whole surface of the semiconductor element 101 and left for 10 minutes, and then the semiconductor 101 is rotated to shake off the alkaline developer from the surface of the surface protection film 103. After that, the state of rotating the semiconductor element 101 is maintained for a predetermined time such as 3 minutes while dropping pure water to the surface of the surface protection film 103, and then dropping pure water is stopped and the pure water is shaken off from the surface of the surface protection film 103 to dry the surface of the surface protection film 103. In this connection, it is preferable to set the predetermined time within the range of 8 to 15 minutes.

When the iodine left on the surface of the surface protection film 103 has been removed by the alkaline developer in this way, the concentration of the iodine left on the surface of the surface protection film 103 has become 3 ng/cm².

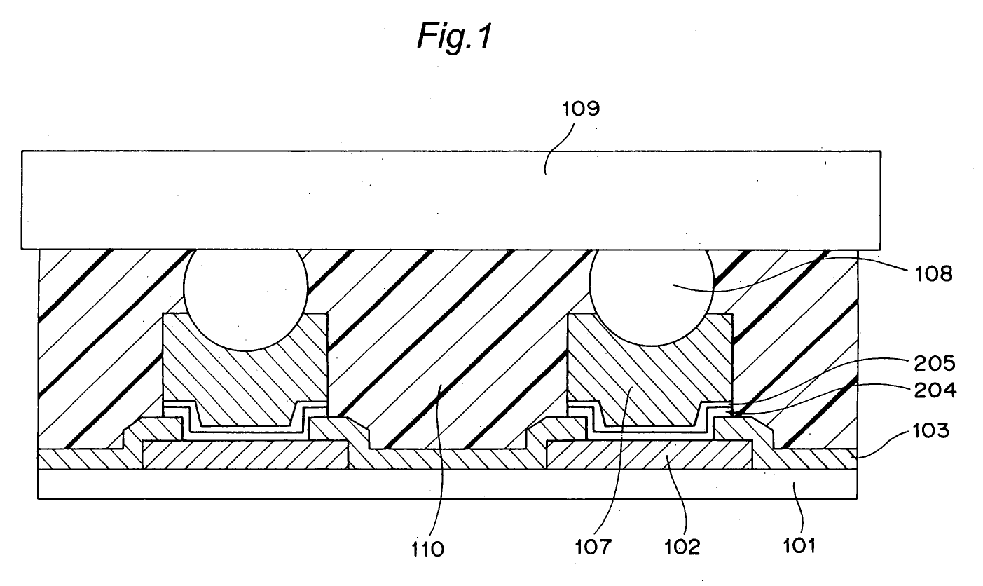

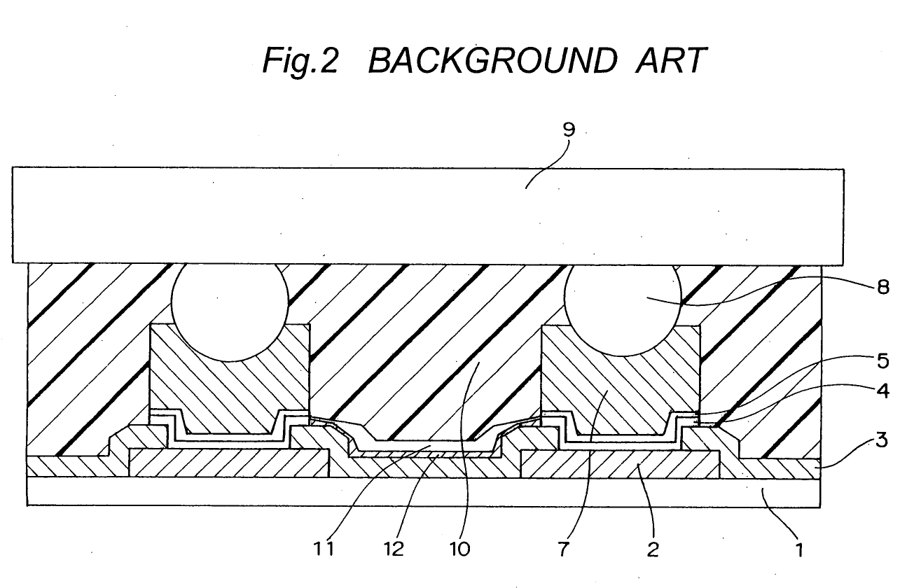

Furthermore, when the semiconductor 101 which has undergone steps S101 to S107 in FIG. 3 is mounted on a tape as shown in FIG. 1, the Au bumps are not electrically shorted to each other during the operation of the semiconductor element 101. In FIG. 1, reference numeral 108 denotes leads, reference numeral 109 denotes a tape, and reference numeral 110 denotes a sealing resin.

When the concentration of residual iodine on the surface of the semiconductor element 101 exceeds 300 ng/cm², electrical short of the Au bumps 107 took place.

Thus, at step S107 in FIG. 3, the Au bumps 107 are surely prevented from being shorted to each other by reducing the concentration of the residual iodine to 300 ng/cm² or less.

Furthermore, even if other alkaline chemical solution of a pH of from 9 to 12 or pure water of a temperature of from 50° C. to 75° C. is used instead of the alkaline developer, the concentration of the residual halogen on the surface of the semiconductor element 101 can be made 3 to 20 ng/cm², and thereby the Au bumps can be prevented from being shorted to each other after mounting the semiconductor element on the tape.

In other words, any liquid which is able to remove the halogen may be used even if it is not alkaline developer. Alkaline chemical solutions of a pH of from 9 to 12 include, for example, an ammonium hydroxide solution, a tetramethylammonium hydroxide (TMAH) solution, and the like.

Furthermore, the method of supplying alkaline developer to the surface of the semiconductor element 101 is not limited to a dropping method and may be a method other than a dropping method. For example, a dip method or the like may be used.

Furthermore, the period of time for which dropped alkaline developer is left on the surface of the semiconductor element is not limited to 10 minutes and may be a period of time other than 10 minutes. However, it is preferable to set the leaving time within the range of 8 to 15 minutes.

In the above embodiment, part of the Au film 105 may be removed using an etchant including halogen other than iodine, that is, any one of fluorine, bromine, chlorine, and astatine.

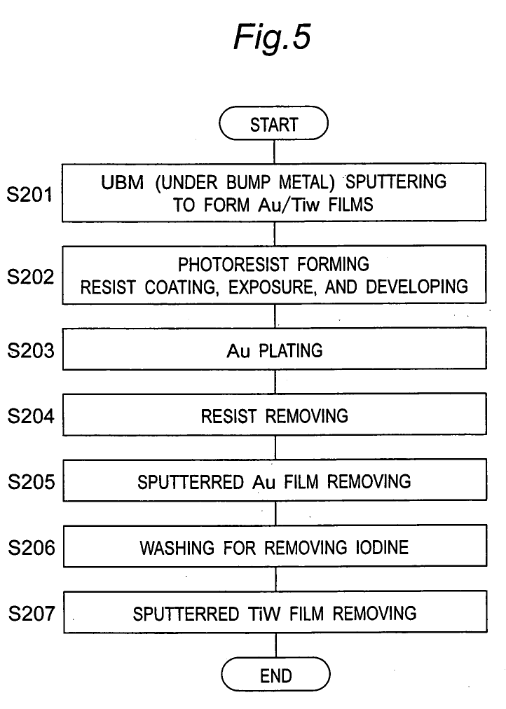

In the above embodiment, washing for removing the iodine of step S107 is performed after removing the sputtered TiW film at step S106. However, as shown in FIG. 5, removing the sputtered TiW film may be performed at step S207 after performing washing for removing the iodine at step S206.

Description about steps S201 to S207 in FIG. 5 is omitted because steps S201 to S205 perform the same processing as steps S101 to S105 in FIG. 3, step S206 performs the same processing as step S107 in FIG. 3, and step S207 performs the same processing as step S106 in FIG. 3.

A semiconductor device manufactured by the method according to the present invention may be used in a driver for a large TFT liquid crystal monitor in which an electrode pitch is small.

Embodiments of the invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

What is claimed is:

1. A method for producing a semiconductor device which comprises a semiconductor element provided with pad electrodes on a surface thereof, comprising:
forming a metal film on the surface of the semiconductor element and on the pad electrodes;
forming metal bumps on the metal film in such a way that the metal bumps are aligned with the pad electrodes;
removing, by wet etching, the metal film in areas where the metal film is not laid on the pad electrodes; and
removing a halogen in the areas from which the metal film has been removed.

2. A method for producing a semiconductor device as claimed in claim 1, wherein the metal film includes an Au film.

3. A method for producing a semiconductor device as claimed in claim 1, wherein the metal film is used as a plating electrode to form the bumps by an electrolytic plating method.

4. A method for producing a semiconductor device as claimed in claim 1, wherein the bumps are formed of Au.

5. A method for producing a semiconductor device as claimed in claim 1, wherein the halogen is removed with an alkaline chemical solution of a pH of from 9 to 12.

6. A method for producing a semiconductor device as claimed in claim 1, wherein the halogen is removed with pure water of a temperature of from 50° C. to 75° C.

7. A method for producing a semiconductor device as claimed in claim 1, wherein the removal of the halogen is performed such that the halogen in the areas where the metal film has been removed is reduced to 300 ng/cm² or less.
